(19) United States
(12) Patent Application Publication
(10) Pub. No.: US 2016/0313419 A1
(43) Pub. Date: Oct. 27, 2016

(54) RADIO FREQUENCY SAFETY SWITCH WITH ADJUSTABLE SWITCHING LEVEL FOR MRI SYSTEMS

(71) Applicant: KONINKLIJKE PHILIPS N.V., Eindhoven (NL)

(72) Inventors: PETER VERNICKEL, EINDHOVEN (NL); OLIVER LIPS, EINDHOVEN (NL); CHRISTIAN FINDEKLEE, EINDHOVEN (NL)

(21) Appl. No.: 15/105,043

(22) PCT Filed: Dec. 16, 2013
(86) PCT No.: PCT/EP2014/078055

§ 371 Date: Jun. 16, 2016

(30) Foreign Application Priority Data
Dec. 20, 2013 (EP) 13198897.4

(51) Int. Cl. G01R 33/36

(52) U.S. Cl. CPC G01R 33/36

(57) ABSTRACT

A radio frequency antenna device (30) for use in a magnetic resonance imaging system (10), the magnetic resonance imaging system (10) being configured for acquiring magnetic resonance images of at least a portion of a subject of interest (20); the radio frequency antenna device (30) comprising—at least one radio frequency antennae (32) that is configured for being fed with radio frequency power from at least one radio frequency channel and for applying a radio frequency field B to nuclei of or within the portion of the subject of interest (20) for magnetic resonance excitation, —at least one pickup circuit (46), including an electric or electronic device having a non-linear current-voltage characteristic, —wherein the at least one pickup circuit (46) is configured to provide a trigger signal (56) upon a transfer of the electric or electronic device between a state of high impedance and a state of low impedance, the trigger signal (56) being exploitable for shutting down a supply of radio frequency power to the at least one radio frequency antenna (32) that is magnetically coupled to the at least one inductor (48); a method of operating a magnetic resonance imaging system (10) in a safe manner with regard to effects of emitted radio frequency power; and a method of operating a magnetic resonance imaging system (10) with regard to calibration of a magnitude of an emitted radio frequency magnetic field B₁.

### FIELD OF THE INVENTION

The invention pertains to a radio frequency antenna device for use in a magnetic resonance imaging system.

### BACKGROUND OF THE INVENTION

In the art of magnetic resonance imaging is well known that employing a plurality of radio frequency antennae configured for simultaneously transmitting radio frequency power and being fed from independent radio frequency channels can lead to improved homogeneity of a radio frequency magnetic field B₁ to be applied to nuclei for generating magnetic resonance excitation. This can be especially beneficial in magnetic resonance imaging systems with a static magnetic field strength of more than 1.5 T. The higher the number of independently transmitting radio frequency antennae in a magnetic resonance imaging system, the higher the technical effort for calibration and for safety monitoring and protection with regard to effects of radio frequency power on human tissue (specific absorption rate SAR) and electronic equipment.

Document US 2012/0306499 describes a radio frequency transmit/receive coil assembly in which radio frequency coil elements are electrically connected to a hybrid power splitter/combiner by failsafe safety switches having a variable impedance, changing their impedance in response to electrical control signals that are supplied to the failsafe safety switches if the radio frequency coil assembly is properly connected.

The international application WO2008/001326 concerns an RF coil system for multi-nuclear imaging. The known coil system comprises a transmitter coil, a planar receiver coil and an on-board digital receiver circuit. The planar receiver coil has tuning capacitors and an active and a passive (de)tuning circuit each bridging a tuning capacitor. The active (de)tuning circuit is controlled by control signals form a control unit. Upon appropriate tuning of the planar receiver coil, magnetic resonance signals of the selected nuclei (in dependence of the tuned resonance frequency) are acquired and provided to the digital receiver circuit.

### SUMMARY OF THE INVENTION

It is an object of the invention to provide a radio frequency antenna device comprising at least one radio frequency antenna for transmitting radio frequency power for use in a magnetic resonance imaging system with a reduced technical effort for calibration and safety monitoring.

This object is achieved by a radio frequency antenna device for use in a magnetic resonance imaging system, the magnetic resonance imaging system being configured for acquiring magnetic resonance images of at least a portion of a subject of interest and including

an examination space provided to position at least the portion of the subject of interest within, and

a main magnet configured for generating a static magnetic field in the examination space.

The radio frequency antenna device comprises

at least one radio frequency antenna that is configured for being fed with radio frequency power from at least one radio frequency channel and for applying a radio frequency field B₁ to nuclei of or within the portion of the subject of interest for magnetic resonance excitation, and

at least one pickup circuit.

The at least one pickup circuit includes

at least one inductor that is magnetically coupled to the at least one radio frequency antenna,

at least one capacitor that is electrically conducted in series to the at least one inductor to form a series resonant circuit that is tunable in a range about the Larmor frequency and,

an electric or electronic device having a non-linear current-voltage characteristic with at least one state of high impedance and at least one state of low impedance, wherein the electric or electronic device can reversibly be transferred between the state of high impedance and the state of low impedance by a voltage change between a first voltage that is smaller than a predetermined threshold voltage and a second voltage that is larger than the predetermined threshold voltage, and wherein the electric or electronic device is connected in parallel to the at least one capacitor.

The at least one pickup circuit is configured to provide a trigger signal upon a transfer of the electric or electronic device between the state of high impedance and the state of low impedance, the trigger signal being exploitable for shutting down a supply of radio frequency power to the at least one radio frequency antenna that is magnetically coupled to the at least one inductor.

The phrase “electronic device”, as used in this application, shall be understood particularly as a device in which an electric current is at least partially established by the transport of charge carriers within a semiconductor, within a space filled with gas or in a vacuum.

The phrase “non-linear current-voltage characteristic”, as used in this application, shall particularly encompass electronic devices whose current-voltage characteristic includes a steep rise enabling the use of the electronic device for switching purposes.

The phrase “directly or indirectly connected in parallel”, as used in this application, shall be understood particularly such that terminals of the capacitor and the electric or electronic device are directly electrically connected (directly connected in parallel), or such that the electric or electronic device is a part of an electric path comprising at least one other electric or electronic device, in particular a resistor, and wherein the electric path is directly connected in parallel to the capacitor.

With a suitably selected predetermined threshold voltage, the supply of radio frequency power can automatically and reliably be shut down at a power level that complies with existing safety regulations regarding exposure of the subject of interest to radio frequency fields, and that is nondestructive for electronic equipment of the magnetic resonance imaging system.

In a preferred embodiment, the electric or electronic device is selected from a group consisting of a spark gap, a varistor, a diode, a transistor, a diac, and a triac.

Spark gaps are available as versatile SMD components, offering a range of selectable parameters like surge current and spark-over voltages with a very high insulation resistance, particularly in comparison to semiconductor devices, a low series capacitance and a generally stable temperature behavior. Sparking can occur hundreds of times without any remarkable degradation of the parameters mentioned.

In the lay-out of the pickup circuit, the spark gap may be designed as a readily exchangeable component by providing easy access for maintenance.

The diode may in particular be formed as a fast switching diode or a light emitting diode (LED). The transistor may in particular be formed as a fast switching metal oxide-semiconductor field-effect transistor (MOSFET).

In this way, a technically simple and cost-effective solution for the at least one pickup circuit can be provided.

Preferably, a coupling coefficient k of the magnetic coupling between the at least one radio frequency antenna and the at least one inductor is selected to be less than one percent. The coupling coefficient k shall be understood in the usual sense to be defined by k=M/(L₁*L₂)^{1/2}, wherein M denotes the mutual inductance between two inductances L₁ and L₂ that are magnetically coupled. By that, the effect of the inductor of the pickup circuit on a current in the at least one radio frequency antenna coupled thereto is negligible. Mostly preferred, the coupling coefficient k is less than 10⁻³, providing a safety margin for not affecting the function of the at least one radio frequency antenna.

In another preferred embodiment, the at least one capacitor is formed by a parasitic capacitance inherent to the electric or electronic device. In this case, the series resonant circuit is tunable by the at least one inductor, and by avoiding a lumped capacitor for the at least one capacitor, a simpler solution for realizing the pickup circuit can be provided.

In yet another preferred embodiment, the radio frequency antenna device comprises a plurality of radio frequency antennae, wherein each radio frequency antenna of the plurality of radio frequency antennae is configured for being fed with radio frequency power at least from the at least one radio frequency channel, and further comprises a plurality of pickup circuits, wherein each radio frequency antenna of the plurality of radio frequency antennae is coupled to at least one pickup circuit of the plurality of pickup circuits. This enables an individual safety monitoring of each radio frequency antenna of the plurality of radio frequency antennae with a reduced technical effort.

Preferably, each radio frequency antenna of the plurality of radio frequency antennae is magnetically coupled to the at least one inductor of the different one of the pickup circuits of the plurality of pickup circuits.

The technical effort is advantageously further reduced if the radio frequency antenna device comprises a multiplexer that is configured to subsequently provide at least one electrical connection between each pickup circuit of the plurality of pickup circuits and an electric or electronic device that is common to the plurality of pickup circuits.

In a further preferred embodiment, the at least one electric or electronic device is formed as a spark gap with a transparent housing, and the trigger signal is at least in a section formed by a light signal. In this way, the trigger signal can be conveyed by non-metallic optical means for being exploited at a remote place.

The radio frequency antenna device may advantageously further comprise a lumped resistor, which is electrically connected in series with the at least one inductor and the at least one capacitor, for adjusting a voltage across the series resonant circuit. The lumped resistor lowers the quality factor of the series resonant circuit, thereby allowing to control the voltage that is inducible by the magnetic coupling to the at least one radio frequency antenna of the plurality of radiofrequency antennae, and to adapt the voltage to the predetermined threshold voltage of the electric or electronic device.

In another preferred embodiment, the at least one pickup circuit further comprises a light emitting diode that is electrically connected in series with the electric or electronic device, wherein the trigger signal is formed by light emitted by the light emitting diode. This provides the advantage that the trigger signal can be conveyed by non-metallic optical means for being exploited at a remote place.

In another aspect of the invention, a magnetic resonance imaging system is provided that is configured for acquiring magnetic resonance images of at least a portion of a subject of interest. The magnetic resonance imaging system comprises an examination space provided to position the subject of interest within, a main magnet configured for generating a static magnetic field in the examination space, and a magnetic gradient coil system configured for generating gradient magnetic fields superimposed to the static magnetic field. The magnetic resonance imaging system further includes at least one of the disclosed embodiments of the radio frequency antenna device or a combination thereof, and at least one radio frequency antenna device that is provided for receiving magnetic resonance signals from the nuclei of or within the portion of the subject of interest that have been excited by transmission of the radio frequency field. Moreover, the magnetic resonance imaging system comprises a control unit that is configured for controlling functions of the magnetic resonance imaging system.

In yet another aspect of the invention, a method of operating a magnetic resonance imaging system as described in the preceding paragraph in a safe manner with regard to effects of emitted radio frequency power is provided.

The method comprises steps of:

couple at least one pickup circuit to at least one radio frequency antenna,

adapt a desired level of voltage inducible across the series resonant circuit or applicable to the electric or electronic device to the predetermined threshold voltage of the electric or electronic device of the at least one pickup circuit,

exploit a trigger signal provided by the at least one pickup circuit by shutting down via the control unit a supply of radio frequency power to the at least one radio frequency antenna that is coupled to the at least one pickup circuit.

Preferably, the at least one radio frequency antenna is magnetically coupled to the at least one inductor of the at least one pickup circuit. By that, a voltage is inducible across the series resonant circuit.

As a further aspect of the invention, a method of operating a magnetic resonance imaging system as described in the preceding paragraph with regard to calibration of a magnitude of an emitted radio frequency magnetic field, is provided. The magnetic resonance imaging system includes a radio frequency antenna device that comprises a plurality of pickup circuits, wherein each radio frequency antenna of the plurality of radio frequency antennae is coupled to at least one pickup circuit of the plurality of pickup circuits.

The method comprises steps of:

selecting a first radio frequency antenna of the plurality of radio frequency antennae for feeding radio frequency power to,

adapt a desired level of voltage inducible across the series resonant circuit or applicable to the electric or electronic device to a first predetermined threshold voltage of the electric or electronic device of the pickup circuit that is coupled to the first radio frequency antenna,

ramping up a level of radio frequency power that is fed to the first radio frequency antenna of the plurality of radio frequency antennae,

exploiting a trigger signal that is provided by the pickup circuit by relating the level of radio frequency power that had been fed to the first radio frequency antenna at the point in time of the occurrence of the trigger signal to an intended magnitude of radio frequency magnetic field generated by the first radio frequency antenna,

shutting down a supply of radio frequency power to the first radio frequency antenna of the plurality of radio frequency antennae,

selecting a second radio frequency antenna of the plurality of radio frequency antennae for feeding radio frequency power to

adapting a desired level of voltage inducible across the series resonant circuit or applicable to the electric or electronic device to a second predetermined threshold voltage of the electric or electronic device of the pickup circuit that is coupled to the second radio frequency antenna and carry out the steps of ramping up, exploiting a trigger signal, and shutting down the supply of radio frequency power,

repeating the precedent step for the remaining radio frequency antennae of the plurality of radio frequency antennae.

In this way, radio frequency reference power for generating a desired radio frequency magnetic field B₁ can be determined for each individual radio frequency antenna of the plurality of radio frequency antennae for a given loading of the radio frequency antennae by the subject of interest. By that, the magnetic resonance imaging system including a radio frequency antenna device having at least one radio frequency antenna that is configured for being fed with radio frequency power from at least one radio frequency channel can be calibrated with a reduced technical effort. A much larger reduction of technical effort unfolds, of course, for a magnetic resonance imaging system including a radio frequency antenna device having a plurality of radio frequency antennae that are configured for being fed with radio frequency power from at least two independent radio frequency channels.

Preferably, each radio frequency antenna of the plurality of radio frequency antennae is magnetically coupled to the at least one inductor of at least one pickup circuit. By that, a voltage is inducible across the series resonant circuit of the pickup circuit.

In an alternative approach, the steps of selecting a first (second) radio frequency antenna may be modified to selecting a first (second) radio frequency antenna for not feeding radio frequency power to, and the step of ramping up a level of radio frequency power may be modified to ramping up a level of radio frequency power that is fed to all but the first (second) radio frequency antennae of the plurality of radio frequency antennae.

Also alternatively, at least one of the pickup circuits of the plurality of pickup circuits may comprise two electric or electronic devices that can optionally, for instance by a switch, the connected in parallel to the at least one capacitor. One of the two electric or electronic devices may have a lower predetermined threshold voltage and may be used for calibration purposes only. In this way, a larger safety margin with regard to specific absorption rate is maintained during calibration.

In a preferred embodiment, the step of adapting a desired level of voltage inducible across the series resonant circuit to a predetermined threshold voltage of the electric or electronic device of a specific pickup circuit is carried out by adjusting the magnetic coupling between the at least one inductor of the specific pickup circuit and the radio frequency antenna. As is commonly known, the parameters determining the mutual inductance between two inductors are their specific shape and their arrangement relative to each other, so that methods of adjusting the magnetic coupling are obvious to the person skilled in the art and need not be described in detail herein.

The step of adapting a desired level of voltage inducible across the series resonant circuit to a predetermined threshold voltage of the electric or electronic device of a specific pickup circuit can preferably also be carried out by selecting a resistance value of a lumped resistor which is electrically connected in series with the at least one inductor and the at least one capacitor. The lumped resistor lowers the quality factor of the series resonant circuit and thereby allows controlling the voltage that is inducible by the magnetic coupling to the specific radio frequency antenna of the plurality of radio frequency antennae.

### BRIEF DESCRIPTION OF THE DRAWINGS

These and other aspects of the invention will be apparent from and elucidated with reference to the embodiments described hereinafter.

In the drawings:

FIG. 1 is a schematic illustration of a part of an embodiment of a magnetic resonance imaging system in accordance with the invention,

FIG. 2 schematically illustrates the radio frequency antenna device of the magnetic resonance imaging system pursuant to FIG. 1,

FIG. 3 is a diagram of a pickup circuit in accordance with the invention,

FIG. 4 shows the result of a SPICE software simulation for one of the radio frequency antenna of the radio frequency antenna device pursuant to FIG. 2, and

FIG. 5 is a diagram of an alternative pickup circuit in accordance with the invention.

### DETAILED DESCRIPTION OF EMBODIMENTS

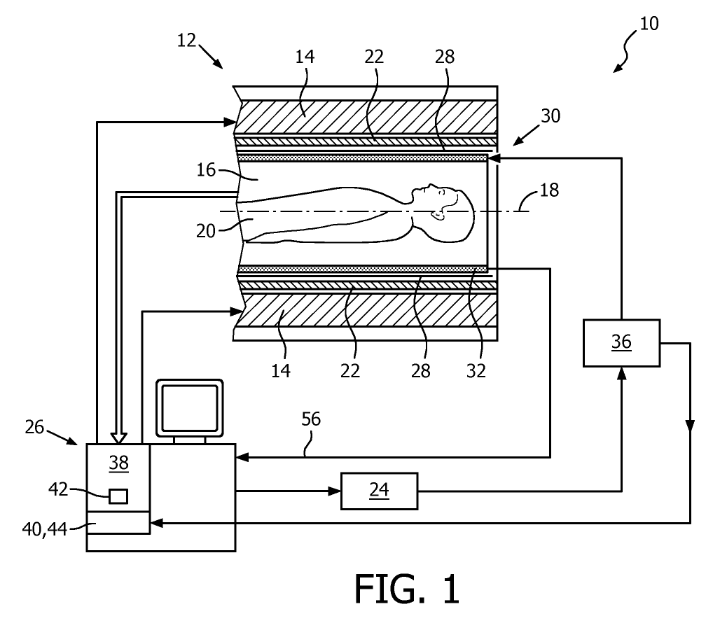

FIG. 1 is a schematic illustration of a part of an embodiment of a magnetic resonance imaging system 10 in accordance with the invention, configured for acquiring magnetic resonance images of at least a portion of a subject of interest 20. The magnetic resonance imaging system 10 comprises a magnetic resonance scanner 12 having a main magnet 14 configured for generating a static magnetic field with a magnetic field strength of 3.0 T. The main magnet 14 has a central bore that provides an examination space 16 around a center axis 18 for positioning the subject of interest 20 within. For clarity reasons, a conventional table for supporting the subject of interest 20 has been omitted in FIG. 1. The substantially static magnetic field defines an axial direction of the examination space 16, aligned in parallel to the center axis 18. Further, the magnetic resonance imaging system 10 includes a magnetic gradient coil system 22 configured for generating gradient magnetic fields superimposed to the static magnetic field. The magnetic gradient coil system 22 is concentrically arranged within the bore of the main magnet 14, as is known in the art.

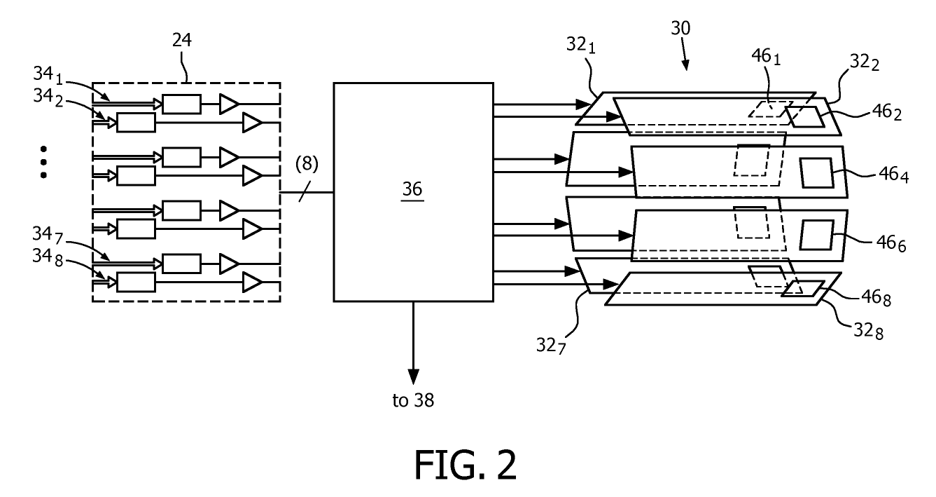

Further, the magnetic resonance imaging system 10 comprises a radio frequency antenna device 30 designed as a whole-body coil. The radio frequency antenna device 30 includes a plurality of eight radio frequency antennae 32₁-32₈ that are configured for being fed with radio frequency power from a radio frequency transmitter unit 24 comprising eight independent radio frequency channels 34₁-34₈, wherein each of the radio frequency channels 34₁-34₈ includes a radio frequency source and a radio frequency power amplifier (FIG. 2). The plurality of eight radio frequency antennae 32₁-32₈ is provided for applying a radio frequency field B₁ to nuclei of or within the portion of the subject of interest 20 for magnetic resonance excitation.

Although in this embodiment the radio frequency antenna device is described to include eight radio frequency antennae, the one skilled in the art would appreciate that the radio frequency antenna device may also comprise a different number of radiofrequency antennae. Also, the number of independent radio frequency channels may be different for other embodiments.

The plurality of eight radio frequency antennae 32₁-32₈ of the radio frequency antenna device 30 is also provided for receiving magnetic resonance signals during radio frequency receive phases from the nuclei of or within the portion of the subject of interest 20 that have been excited by the transmitted radio frequency field B₁. In an operational state of the magnetic resonance imaging system 10, radio frequency transmit phases and radio frequency receive phases are taking place in a consecutive manner. The plurality of eight radio frequency antennae 32₁-32₈ has a center axis that, in the operational state, is arranged concentrically within the bore of the main magnet 14 such that the center axis of the plurality of eight radio frequency antennae 32₁-32₈ and the center axis 18 of the magnetic resonance imaging system 10 coincide. As is well known in the art, a cylindrical metal radio frequency screen 28 is arranged concentrically between the magnetic gradient coil system 22 and the plurality of eight radio frequency antennae 32₁-32₈.

As shown in FIG. 1, the magnetic resonance imaging system 10 further includes a control unit 26 provided for at least controlling functions of the magnetic resonance scanner 12 and the magnetic gradient coil system 22. Moreover, the radio frequency transmitter unit 30 is connected to and controlled by the control unit 26. The radio frequency transmitter unit 30 is provided to feed radio frequency power of a magnetic resonance radio frequency to the plurality of eight radio frequency antennae 32₁-32₈ via a radio frequency switching unit 36 during the radio frequency transmit phases. During radio frequency receive phases, the radio frequency switching unit 36 directs the magnetic resonance signals from the radio frequency antennae 32₁-32₈ to an image processing unit 38 residing in the control unit 26. The image processing unit 38 is configured for processing acquired magnetic resonance signals to determine a magnetic resonance image of the portion of the subject of interest 20 from the acquired magnetic resonance signals. Many different variations of this technique are well known to the person skilled in the art, and thus need not be described in further detail herein.

The radio frequency antenna device 30 further includes a plurality of eight pickup circuits 46₁-46₈ (FIG. 2). Each pickup circuit 46ₙ of the plurality of pickup circuits 46₁-46₈ is arranged in the vicinity of a different one of the radio frequency antenna 32ₙ of the plurality of radio frequency antennae 32₁-32₈. In this way, each radio frequency antenna 32ₙ of the plurality of radio frequency antennae 32₁-32₈ is magnetically coupled to a different one of the pickup circuits 46ₙ of the plurality of pickup circuits 46₁-46₈.

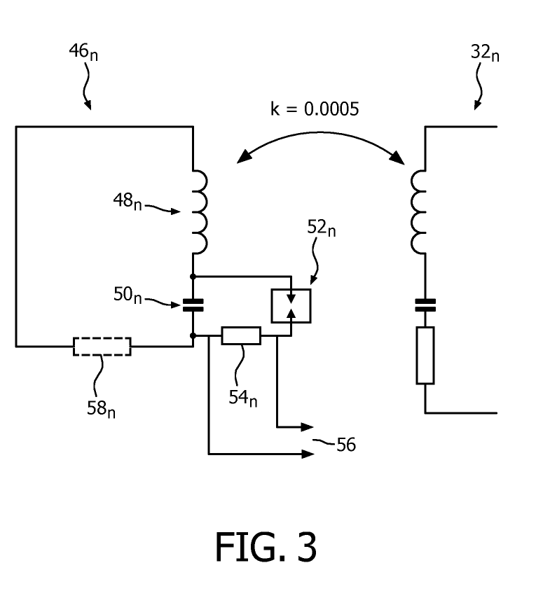

A diagram of one of the pickup circuits 46ₙ and a part of the radio frequency antenna 32ₙ is shown in FIG. 3. The radio frequency antennae 32ₙ of the plurality of eight radio frequency antennae 32₁-32₈ are identically designed, each radio frequency antenna 32ₙ comprising a flat rectangular coil and a tuning capacitor for tuning the radio frequency antenna 32ₙ to the Larmor frequency.

The pickup circuits 46ₙ of the plurality of eight pickup circuits 46₁-46₈ are identically designed and each include an inductor 48ₙ that is magnetically coupled to the flat rectangular coil of the radio frequency antenna 32ₙ in whose vicinity it is arranged. The relative position and orientation of each pickup circuit 46ₙ of the plurality of eight pickup circuits 46₁-46₈ and the radio frequency antenna 32ₙ it is magnetically coupled to is selected such that a coupling coefficient k between the inductor 48ₙ of the pickup circuit 46ₙ and the flat rectangular coil of the radio frequency antenna 32ₙ is less than one percent, namely about 0.0005. A magnetically coupling to the more remote radio frequency antennae 32₁-32₈ is much lower due to the greater distance, and therefore negligible.

Each pickup circuit 46ₙ further comprises a capacitor 50ₙ that is electrically connected in series to the inductor 48ₙ to form a series resonant circuit that is tuned to a resonance frequency that lies in a range about the Larmor frequency. Electrically connected in parallel to the capacitor 50ₙ, each pickup circuit 46ₙ includes an electronic device formed by an SMD-type spark gap 52ₙ and a reference resistor 54ₙ of low resistance, e.g. of 0.1 Ohm. Alternatively, the electronic device could be selected from a group consisting of a varistor, a diode, a transistor and a diac. In principle, any electronic device having a non-linear current-voltage characteristic that appears to be suitable to the person skilled in the art could be employed, provided that the pickup circuit was suitably modified.

The spark gap 52ₙ has a non-linear current-voltage characteristic with a state of high impedance of more than 100 MOhm and a state of low impedance. The spark gap 52ₙ can reversibly be transferred between the state of high impedance and the state of low impedance by a voltage change between a first voltage that is smaller than a predetermined threshold voltage and a second voltage that is larger than the predetermined threshold voltage of the spark gap 52ₙ. The predetermined threshold voltage of the spark gap 52ₙ is given by a spark-over voltage of 250 V for radio frequencies of about the Larmor frequency.

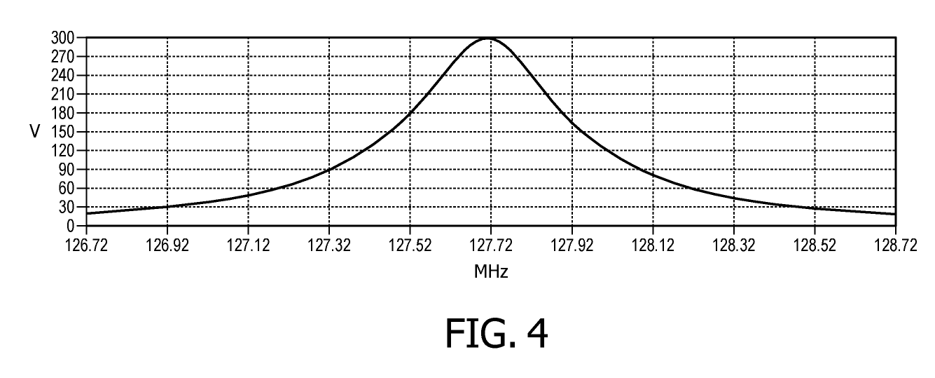

FIG. 4 shows the result of a SPICE software simulation for one of the radio frequency antenna 32ₙ of the radio frequency antenna device 30 pursuant to FIG. 2 being magnetically coupled to the inductor 48ₙ of the pickup circuit 46ₙ pursuant to FIG. 3. The radio frequency power is fed to the radio frequency antenna 32ₙ with a voltage amplitude of 200 V, generating a current of 14 A in the radio frequency antenna 32ₙ. In the diagram, the voltage across the capacitor 50ₙ is illustrated in a radio frequency range around the resonance frequency of the series resonant circuit which lies in the vicinity of the Larmor frequency. As shown, a peak voltage reaches up to 300 V, limited by the inherent ohmic resistances of the inductor 48ₙ and the capacitor 50ₙ. This peak voltage is sufficient to transfer the spark gap 52ₙ from the state of high impedance to the state of low impedance. When such a transfer occurs, an electric current through the reference resistor 54ₙ changes which is, for instance, detectable as a rise in the voltage across the reference resistor 54ₙ. Methods to detect such a rise in voltage need not be described in more detail herein, as they are well known in the art.

In this way, the pickup circuit 46ₙ is configured to provide a trigger signal 56ₙ upon a transfer of the spark gap 52ₙ between the state of high impedance and the state of low impedance, wherein the trigger signal 56ₙ is formed by the rise in the voltage across the reference resistor 54ₙ.

In an alternative approach (not illustrated), the pickup circuit 46ₙ of FIG. 3 can be simplified by leaving out the lumped capacitor 50ₙ, so that the parasitic capacitance inherent to the spark gap 52ₙ is electrically connected in series to the inductor 48ₙ, forming a series resonant circuit that is tunable to a vicinity of the Larmor frequency by selecting a suitable inductance value of the inductor 48ₙ.

Further, and also alternatively (not illustrated), the radio frequency antenna device 30 may comprise a multiplexer that is configured to subsequently provide at least one electrical connection between the at least one capacitor 50ₙ of each pickup circuit 46ₙ of the plurality of pickup circuits 46₁-46₈ and an electric or electronic device that is common to the plurality of pickup circuits 46₁-46₈.

It is appreciated by the person skilled in the art that a tuning of the resonance frequency of the series resonant circuit relative to the Larmor frequency is a viable option for adapting a desired level of voltage inducible across the series resonant circuit to the predetermined threshold voltage of the spark gap 52ₙ.

A second viable option for adapting a desired level of voltage inducible across the series resonant circuit to the predetermined threshold voltage of the spark gap 52ₙ is given by selecting a resistance value of a lumped resistor 58ₙ which is electrically connected in series with the at least one inductor 48ₙ and the at least one capacitor 50ₙ. Such a lumped resistor 58ₙ is indicated in FIG. 3 by dashed line.

A third option for adapting a desired level of voltage inducible across the series resonant circuit to the predetermined threshold voltage of the spark gap 52ₙ is given by adjusting the magnetic coupling between the inductor 48ₙ of the pickup circuit 46ₙ and the radio frequency antenna 32ₙ which the inductor 48ₙ is coupled to. This option is viable as long as the current in the radio frequency antenna 32ₙ is affected only within specified limits, for instance within 0.2%.

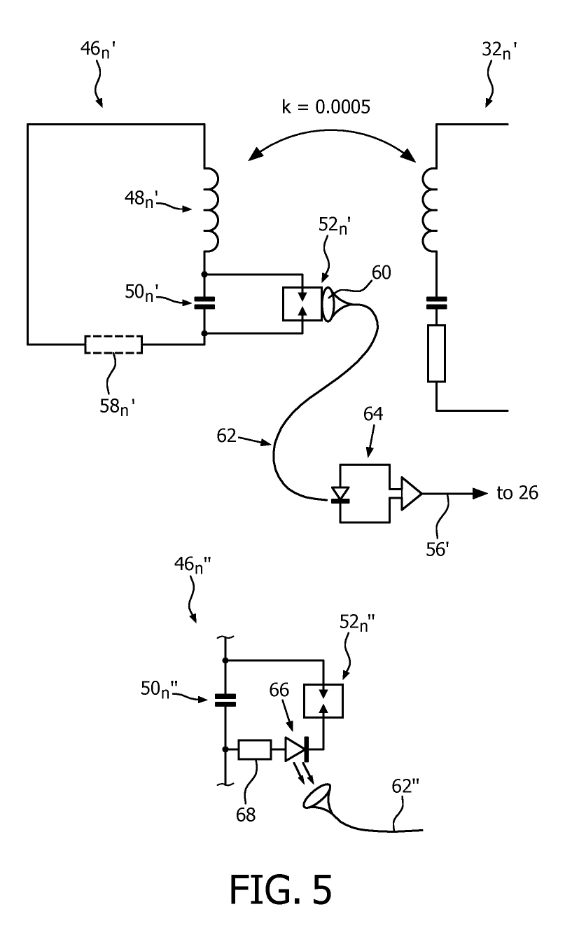

FIG. 5 shows a diagram of an alternative pickup circuit 46ₙ′ in accordance with the invention. In contrast to the embodiment pursuant to FIG. 3, the electronic device is formed as a spark gap 52ₙ′ with a transparent housing. A plastic optic lens 60 is attached to the transparent housing, and an optical fiber 62 is spliced to the optic lens 60. A transfer between the high impedance state and the low impedance state of the spark gap 52ₙ′ goes along with an emission of light, part of which will be coupled by the optical lens 60 to the optical fiber 62 and which can be transmitted towards a remote light detector 64 so as to generate a trigger signal 56′ that can be transmitted to the control unit 26 of the magnetic resonance imaging system 10 for further exploitation. The remote light detector 64 may be arranged, for instance, close to the control unit 26.

Instead of employing a spark gap 52ₙ′ with a transparent housing, a spark gap 52ₙ″ with a regular housing could be used in an alternative pickup circuit 46″ if the spark gap 52ₙ″ was electrically connected in series with a light emitting diode 66 and a series resistor 68, the series combination of spark gap 52ₙ″, light emitting diode 66 and series resistor 68 being electrically connected in parallel to the capacitor, as shown in FIG. 5 in dashed line. An optical fiber 62″ could be attached to a light emitting diode 66″ in the same way as described before.

In the following, a method of operating the magnetic resonance imaging system 10 in a safe manner with regard to effects of emitted radio frequency power is described. In preparation of operating the magnetic resonance imaging system 10, it shall be understood that all involved units and devices are in an operational state, that each radio frequency antenna 32ₙ of the plurality of radio frequency antennae 32₁-32₈ is magnetically coupled to the inductor 48₁-48₈ of a different one of the pickup circuits 46ₙ of the plurality of pickup circuits 46₁-46₈, and that the levels of voltage inducible across the series resonant circuits have been adapted to the predetermined threshold voltages of the spark gaps 52₁-52₈.

Initially, all spark gaps 52₁-52₈ in the pickup circuits 46₁-46₈ are in the state of high impedance. If during one of the radio frequency transmit phases of the magnetic resonance imaging system 10 one of the spark gaps 52ₙ is transferred from its state of high impedance to its state of low impedance by the voltage induced in the pickup circuit 46ₙ exceeding the predetermined threshold voltage of the spark gap 52ₙ, a trigger signal 56ₙ is provided by the pickup circuit 46ₙ in the form of a voltage rise across the reference resistor 54ₙ.

The voltages across the reference resistor 54ₙ of each of the pickup circuits 46₁-46₈ are transmitted via suitable means not illustrated in FIG. 3 to the control unit 26 of the magnetic resonance imaging system 10. Suitable means include cable connections transmitting the analog voltages, or analog-to-digital conversion of the voltages and transmission of digital data representing the voltages via cabling or via a wireless connection to the control unit 26, and may further include other means that appear suitable to the person skilled in the art.

Upon occurrence of the trigger signal 56 and its detection in the control unit 26, the trigger signal 56 is exploited by shutting down via the control unit 26 the supply of radio frequency power to the radio frequency antenna 32ₙ that is magnetically coupled to the inductor 48ₙ of the pickup circuit 46ₙ that provided the trigger signal 56. In this way, any harm to the subject of interest 20 by excessive exposure to radio frequency power and destruction of sensitive electronic equipment of the magnetic resonance imaging system 10 can effectively be prevented.

Next, a method of operating the magnetic resonance imaging system 10 in a safe manner with regard to calibration of a magnitude of an emitted radio frequency field B₁ is described. Again, it shall be understood that in preparation of operating the magnetic resonance imaging system 10, all involved units and devices are in an operational state, that each radio frequency antenna 32ₙ of the plurality of radio frequency antennae 32₁-32₈ is magnetically coupled to the inductor 48ₙ of a different one of the pickup circuits 46ₙ of the plurality of pickup circuits 46₁-46₈, and that the levels of voltage inducible across the series resonant circuits have been adapted to the predetermined threshold voltages of the spark gaps 52ₙ, and all spark gaps 52₁-52₈ in the pickup circuits 46₁-46₈ are initially in their state of high impedance.

Steps of the method are controlled by the control unit 26 of the magnetic resonance imaging system 10. To this end, the control unit 26 comprises a software module 44 (FIG. 1). The method steps to be conducted are converted into a program code of the software module 44, wherein the program code is implementable in a memory unit 40 of the control unit 26 and is executable by a processor unit 42 of the control unit 26. In this embodiment, the control unit 26 that is customary for controlling functions of the magnetic resonance imaging system 10 has been employed to carry out the steps of the method. In principle, the control unit 26 may alternatively be designed as an additional control unit that is especially assigned to execute the method steps.

The method is automatically carried out upon initiation by input of an operator of the magnetic resonance imaging system 10. The control unit 26 selects a first radio frequency antenna 32ₙ of the plurality of radio frequency antennae 32₁-32₈ for feeding radio frequency power to by linearly ramping up a level of radio frequency power. Once the voltage induced in the pickup circuit 46ₙ comprising the inductor 48ₙ that is magnetically coupled to the first radio frequency antenna 32ₙ reaches the predetermined threshold voltage of the spark gap 52ₙ, a trigger signal 56ₙ is provided as described earlier. The trigger signal 56ₙ is exploited by relating the level of radio frequency power that had been fed to the first radio frequency antenna 32ₙ at the point in time of the occurrence of the trigger signal 56ₙ to an intended magnetic magnitude of radio frequency field B₁ generated by the first radio frequency antenna 32ₙ. The magnetic coupling between the first radio frequency antenna 32ₙ and the inductor 48ₙ of the pickup circuit 46ₙ ensures that the trigger signal 56ₙ indicates that the same level of magnetic field magnitude of the radio frequency field B₁ that is relevant for the magnetic coupling is generated by the radio frequency antenna 32ₙ.

The level of radio frequency power that was fed at the time of occurrence of the trigger signal 56ₙ is read out and stored in the memory unit 40 of the control unit 26. Then, the supply of radio frequency power to the first radio frequency antenna 32ₙ is shut down, and a second radio frequency antenna 32ₘ of the plurality of radio frequency antennae 32₁-32₈ is selected for feeding radio frequency power to, and the steps of ramping up, exploiting a trigger signal 56ₙ, storing the level of radio frequency power in the memory unit 40, and shutting down the supply of radio frequency power are carried out as before at the first radio frequency antenna 32ₙ.

These steps are then repeated for the remaining radio frequency antenna 32ᵣ (r≠m, n) of the plurality of radio frequency antennae 32₁-32₈.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

REFERENCE SYMBOL LIST

| | | | |
|---|---|---|---|
| 10 | magnetic resonance imaging | B₁ | radio frequency field |
| | system | | |
| 12 | magnetic resonance scanner | k | coupling coefficient |
| 14 | main magnet | | |
| 16 | examination space | | |
| 18 | center axis | | |
| 20 | subject of interest | | |
| 22 | magnetic gradient coil system | | |
| 24 | radio frequency transmitter unit | | |
| 26 | control unit | | |
| 28 | radio frequency screen | | |
| 30 | radio frequency antenna device | | |
| 32 | radio frequency antenna | | |
| 34 | radio frequency channel | | |
| 36 | radio frequency switching unit | | |
| 38 | image processing unit | | |
| 40 | memory unit | | |
| 42 | processor unit | | |
| 44 | software module | | |
| 46 | pickup circuit | | |
| 48 | inductor | | |
| 50 | capacitor | | |
| 52 | spark gap | | |
| 54 | reference resistor | | |
| 56 | trigger signal | | |
| 58 | resistor | | |
| 60 | plastic optic lens | | |
| 62 | optical fiber | | |
| 64 | light detector | | |
| 66 | light emitting diode | | |
| 68 | series resistor | | |

1. A radio frequency antenna device for use in a magnetic resonance imaging system, the magnetic resonance imaging system being configured for acquiring magnetic resonance images of at least a portion of a subject of interest and including
an examination space provided to position at least the portion of the subject of interest within,
a main magnet configured for generating a static magnetic field in the examination space;
the radio frequency antenna device comprising:
at least one radio frequency antenna that is configured for receiving radio frequency power from at least one radio frequency channel and for applying a radio frequency field B1 to nuclei of or within the portion of the subject of interest for magnetic resonance excitation,
at least one pickup circuit, including
at least one inductor that is magnetically coupled to at least one radio frequency antenna of the plurality of radio frequency antennae,
at least one capacitor that is electrically connected in series to the at least one inductor to form a series resonant circuit that is tunable in a range about the Larmor frequency and,
an electric or electronic device having a non-linear current-voltage characteristic with at least one state of high impedance and at least one state of low impedance, wherein the electric or electronic device can reversibly be transferred between the state of high impedance and the state of low impedance by a voltage change between a first voltage that is smaller than a predetermined threshold voltage and a second voltage that is larger than the predetermined threshold voltage, and wherein the electric or electronic device is directly or indirectly connected in parallel to the at least one capacitor (50),
wherein the at least one pickup circuit is configured to, upon a transfer of the electric or electronic device between the state of high impedance and the state of low impedance, the trigger signal, provide a trigger signal to shut down a supply of radio frequency power to the at least one radio frequency antenna that is magnetically coupled to the at least one inductor.

2. The radio frequency antenna device as claimed in claim 1, wherein the electric or electronic device is selected from a group consisting of a spark gap, a varistor, a diode, a transistor, a diac, and a triac.

3. The radio frequency antenna device as claimed in claim 1, wherein a coupling coefficient of the magnetic coupling between the at least one radio frequency antenna and the at least one inductor is selected to be less than one percent.

4. The radio frequency antenna device as claimed in claim 1, wherein the at least one capacitor is formed by a parasitic capacitance inherent to the electric or electronic device.

5. The radio frequency antenna device as claimed in claim 1, comprising a plurality of radio frequency antennae, wherein each radio frequency antenna of the plurality of radio frequency antennae is configured for being fed with radio frequency power at least from the at least one radio frequency channel, and further comprises a plurality of pickup circuits, wherein each radio frequency antenna of the plurality of radio frequency antennae is coupled to at least one pickup circuit of the plurality of pickup circuits.

6. The radio frequency antenna device as claimed in claim 5, comprising a multiplexer that is configured to subsequently provide at least one electrical connection between each pickup circuit of the plurality of pickup circuits and an electric or electronic device that is common to the plurality of pickup circuits.

7. The radio frequency antenna device as claimed in claim 1, wherein at least one electric or electronic device is formed as a spark gap with a transparent housing, and wherein the trigger signal is at least in a section formed by a light signal.

8. The radio frequency antenna device as claimed in claim 1, further comprising a lumped resistor, which is electrically connected in series with the at least one inductor and the at least one capacitor, for adapting a voltage inducible across the series resonant circuit.

9. The radio frequency antenna device as claimed in claim 1, further comprising a light emitting diode that is electrically connected in series with the electric or electronic device, wherein the trigger signal is formed by light emitted by the light emitting diode.

10. A magnetic resonance imaging system, configured for acquiring magnetic resonance images of at least a portion of a subject of interest, comprising:
an examination space provided to position the subject of interest within;
a main magnet configured for generating a static magnetic field in the examination space;
a magnetic gradient coil system configured for generating gradient magnetic fields superimposed to the static magnetic field;
at least one radio frequency antenna device at least one radio frequency antenna that is configured for receiving radio frequency power from at least one radio frequency channel and for applying a radio frequency field B1 to nuclei of or within the portion of the subject of interest for magnetic resonance excitation,
at least one pickup circuit, including: at least one inductor that is magnetically coupled to at least one radio frequency antenna of the plurality of radio frequency antennae, at least one capacitor that is electrically connected in series to the at least one inductor to form a series resonant circuit that is tunable in a range about the Larmor frequency and, an electric or electronic device having a non-linear current-voltage characteristic with at least one state of high impedance and at least one state of low impedance, wherein the electric or electronic device can reversibly be transferred between the state of high impedance and the state of low impedance by a voltage change between a first voltage that is smaller than a predetermined threshold voltage and a second voltage that is larger than the predetermined threshold voltage, and wherein the electric or electronic device is directly or indirectly connected in parallel to the at least one capacitor, wherein the at least one pickup circuit is configured to, upon a transfer of the electric or electronic device between the state of high impedance and the state of low impedance, the trigger signal, provide a trigger signal to shut down a supply of radio frequency power to the at least one radio frequency antenna that is magnetically coupled to the at least one inductor;
at least one radio frequency antenna device that is provided for receiving magnetic resonance signals from the nuclei of or within the portion of the subject of interest that have been excited by transmission of the radio frequency field B1;
a control unit configured for controlling functions of the magnetic resonance imaging system;
wherein the control unit is configured to couple at least one pickup circuit to at least one radio frequency antenna,
adapt a desired level of voltage inducible across the series resonant circuit or applicable to the electric or electronic device to the predetermined threshold voltage of the electric or electronic device of the at least one pickup circuit, and
exploit a trigger signal provided by the at least one pickup circuit by shutting down via the control unit a supply of radio frequency power to the at least one radio frequency antenna that is coupled to the at least one pickup circuit.

11. A method of operating a magnetic resonance imaging system in a safe manner with regard to effects of emitted radio frequency power, the magnetic resonance imaging system being configured for acquiring magnetic resonance images of at least a portion of the subject of interest and including
an examination space provided to position at least the portion of the subject of interest within;
a main magnet for generating a static magnetic field in the examination space;
a magnetic gradient coil system for generating gradient magnetic fields superimposed to the static magnetic field;
at least one radio frequency antenna device as claimed in claim 1;
at least one radio frequency antenna device that is provided for receiving magnetic resonance signals from the nuclei of or within the subject of interest that have been excited by transmission of the radio frequency field B1;
a control unit for controlling functions of the magnetic resonance imaging system 10);
the method comprising steps of
couple at least one pickup circuit to at least one radio frequency antenna,
adapt a desired level of voltage inducible across the series resonant circuit or applicable to the electric or electronic device to the predetermined threshold voltage of the electric or electronic device of the at least one pickup circuit, and
exploit a trigger signal provided by the at least one pickup circuit by shutting down via the control unit a supply of radio frequency power to the at least one radio frequency antenna that is coupled to the at least one pickup circuit.

12. A method of operating a magnetic resonance imaging system with regard to calibration of a magnitude of an emitted radio frequency magnetic field B1, the magnetic resonance imaging system being configured for acquiring magnetic resonance images of at least a portion of the subject of interest and including:
an examination space provided to position at least the portion of the subject of interest within;
a main magnet for generating a static magnetic field in the examination space;
a magnetic gradient coil system for generating gradient magnetic fields superimposed to the static magnetic field;
at least one radio frequency antenna device as claimed in claim 5;
at least one radio frequency antenna device that is provided for receiving magnetic resonance signals from the nuclei of or within the subject of interest that have been excited by transmission of the radio frequency field B1;
a control unit for controlling functions of the magnetic resonance imaging system;
the method comprising steps of:
selecting a first radio frequency antenna of the plurality of radio frequency antennae for feeding radio frequency power to,
adapt a desired level of voltage inducible across the series resonant circuit or applicable to the electric or electronic device to a predetermined threshold voltage of the electric or electronic device of the pickup circuit that is coupled to the first radio frequency antenna,
ramping up a level of radio frequency power that is fed to the first radio frequency antenna of the plurality of radio frequency antennae,
exploiting a trigger signal that is provided by the pickup circuit by relating the level of radio frequency power that had been fed to the first radio frequency antenna at the point in time of the occurrence of the trigger signal to an intended magnitude of radio frequency magnetic field B1 generated by the first radio frequency antenna,
shutting down a supply of radio frequency power to the first radio frequency antenna of the plurality of radio frequency antennae,
selecting a second radio frequency antenna of the plurality of radio frequency antennae for feeding radio frequency power to,
adapting a desired level of voltage inducible across the series resonant circuit or applicable to the electric or electronic device to a second predetermined threshold voltage of the electric or electronic device of the pickup circuit that is coupled to the second radio frequency antenna and carry out the steps of ramping up, exploiting a trigger signal, and shutting down the supply of radio frequency power, and
repeating the precedent steps for the remaining radio frequency antennae of the plurality of radio frequency antennae.

13. The method as claimed in claim 11 of operating a magnetic resonance imaging system, wherein the step of adapting a desired level of voltage inducible across the series resonant circuit to a predetermined threshold voltage of the electric or electronic device of a specific pickup circuit is carried out by adjusting the magnetic coupling between the at least one inductor of the specific pickup circuit and the radio frequency antenna.

14. The method of operating a magnetic resonance imaging system as claimed in claim 11, wherein the step of adapting a desired level of voltage inducible across the series resonant circuit to a predetermined threshold voltage of the electric or electronic device of a specific pickup circuit is carried out by selecting a resistance value of a lumped resistor which is electrically connected in series with the at least one inductor and the at least one capacitor.

15. A software module for carrying out the method as claimed in claim 12, wherein the method steps to be conducted are converted into a program code of the software module, wherein the program code is implementable in a memory unit of the control unit of the magnetic resonance imaging system and is executable by a processor unit of the control unit of the magnetic resonance imaging system.
